(19) United States
(12) Patent Application Publication
(10) Pub. No.: US 2011/0014395 A1
(43) Pub. Date: Jan. 20, 2011

(54) METHOD FOR DEPOSITING A FLUORINATED LAYER FROM A PRECURSOR MONOMER

(75) Inventors: Francois Reniers, Bruxelles (BE); Nicolas Vandencasteele, Bruxelles (BE); Olivier Bury, Mont Sur Marchienne (BE)

Correspondence Address: MERCHANT & GOULD PC, P.O. BOX 2903, MINNEAPOLIS, MN, 55402-0903, US

(73) Assignee: Universite Libre de Bruxelles, Bruxelles (BE)

(21) Appl. No.: 12/676,692

(22) PCT Filed: Sep. 5, 2008
(86) PCT No.: PCT/EP2008/061814

§ 371 Date: Aug. 31, 2010

(30) Foreign Application Priority Data
Sep. 6, 2007 (EP) 07115864.6
Mar. 6, 2008 (EP) 08152409.2

(51) Int. Cl. C23C 16/00

(52) U.S. Cl. 427/569

(57) ABSTRACT

A method for depositing a fluorinated layer on a substrate includes the injection of a gas mixture including a fluorinated compound and a carrier gas in a discharge or post-discharge area of a cold atmospheric plasma at a pressure comprised between 0.8 and 1.2 bars. The fluorinated compound has a boiling temperature at a pressure of 1 bar above 25° C.

### FIELD OF THE INVENTION

The invention relates to the deposition of thin layers of hydrophobic compounds at the surface of a substrate.

### STATE OF THE ART

Modifications of surfaces in order to impart new properties to them are customary things. In this approach, in order to make anti-adhesive surfaces (including towards proteins) dirt-repellent or further (ultra)hydrophobic, it is common to deposit at the surface of the latter a layer, totally or partly consisting of fluorinated molecules.

These methods are presently mainly achieved by the PACVD (plasma assisted chemical vapor deposition) or PECVD (plasma enhanced chemical vapor deposition) technique. The usual technique consists of injecting into a plasma reactor, operating at low pressure, a fluorinated gas monomer (CF₄ being the simplest, but many alternatives exist, such as C₂F₆, C₃F₈, C₄F₈, fluoroalkylsilanes, eta . . . ).

The type of plasma used (RF, microwave plasma, . . . ) differs depending on the studies, but the principle remains the same. The precursor is activated in the low pressure discharge and plasma polymerization takes place in the gas phase or at the interface. The main limitation in these techniques lies in the fact that they imperatively take place at low pressure (under vacuum).

Document US2004/0247886 describes a film deposition method, in which a plasmagenic gas is put into contact with a gas comprising a reactive fluorinated compound in the post-discharge area of an atmospheric plasma, the plasmagenic gas being injected alone into the plasma area. The major drawback of this type of method is that it requires the use of sufficiently reactive compounds. Most of these reactive compounds then have the drawback either of directly bearing hydrophilic polar groups, or of reacting in the long term with atmospheric oxygen or humidity, generating polar groups, and therefore reducing the hydrophobicity of the surface.

Generally, a limitation of most of these techniques is that they require the use of extremely reactive gases and therefore dangerous to transport, store and handle. These gases are also strong generators of greenhouse gas effects and their use is controlled by the Kyoto protocol. These constraints contribute to limiting depositions of fluorinated layers to products with high added value.

### OBJECTS OF THE INVENTION

The object of the present invention is to propose a method for depositing a fluorinated layer from a precursor monomer which avoids the drawbacks of existing methods. In particular, it attempts to avoid the requirement of operating at reduced pressure. Its object is also to allow the use of liquid monomers which are easier to handle than gas monomers and often less controversial on the toxicological and environmental level.

### SUMMARY OF THE INVENTION

The present invention relates to a method for depositing a fluorinated layer on a substrate, comprising the injection of a gas mixture including a fluorinated compound and a carrier gas in a discharge or post-discharge area of a cold atmospheric plasma at a pressure comprised between 0.8 and 1.2 bars, characterized in that said fluorinated compound has a boiling temperature at a pressure of 1 bar above 25° C.

By <<atmospheric plasma>> or, <<cold atmospheric plasma>> is meant a partly or totally ionized gas which comprises electrons, (molecular or atomic) ions, atoms or molecules, and radicals, far from thermodynamic equilibrium, the electron temperature of which is significantly higher than that of the ions and of the neutrals, and the pressure of which is comprised between about 1 mbar and about 1,200 mbars, preferentially between 800 and 1,200 mbars.

In a preferred embodiment of the present invention, the method comprises the steps of:
bringing the carrier gas into contact with the liquid fluorinated compound;
saturating said carrier gas with vapor of said fluorinated compound in order to form a gas mixture;
bringing said gas mixture into the discharge area of an atmospheric plasma;
placing a substrate in the discharge or post-discharge area of said atmospheric plasma.

Preferably, said fluorinated compound does not comprise any hydrogen atom or any oxygen atom.

Preferably, the method does not comprise any plasma-free post-treatment.

In a particular embodiment of the invention, the fluorinated compound is a compound selected from the group consisting of C₆F₁₄, C₇F₁₆, C₈F₁₈, C₉F₂₀ and C₁₀F₂₂, or mixtures thereof.

Preferably, the fluorinated compound is perfluorohexane (C₆F₁₄).

In another preferred embodiment of the invention, the fluorinated compound is of the type:

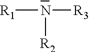

wherein R₁, R₂ and R₃ are groups of the perfluoroalkane type of formula CₙF₂ₙ₊₁, or a mixture of these compounds.

Preferably, the fluorinated compound is perfluorotributylamine ((C₄F₉)₃N) (CAS No. 311-89-7).

Preferably, the vapor pressure of said fluorinated compound at room temperature is comprised between 1 mbar et 1 bar.

In a preferred embodiment of the present invention, the partial pressure of said fluorinated compound in said carrier gas is regulated by controlling the temperature of a bath of said fluorinated compound into which the carrier gas is injected before injection into the plasma.

Preferably, the temperature of the bath is maintained at a temperature at which the vapor pressure of said compound is less than 10 mbars, preferably less than 2 mbars.

In a preferred embodiment of the invention, said fluorinated compound has a vapor pressure at 25° C., of less than 10 mbars, preferably less than 2 mbars.

In a preferred embodiment of the invention, the atmospheric plasma is produced by a device of the dielectric barrier type.

In a preferred embodiment of the invention, the atmospheric plasma is produced by a device of the type using microwaves.

Preferably, the carrier gas is a gas having low reactivity selected from the group consisting of: nitrogen and a rare gas or mixtures thereof, preferably a rare gas or a rare gas mixture, preferably argon.

In a particular embodiment of the invention the substrate comprises a deposit surface comprising a polymer, in particular PVC or polyethylene.

In another embodiment, the substrate comprises a deposition surface comprising a metal, or a metal alloy, in particular steel.

In another embodiment of the present invention, the substrate comprises a deposition surface comprising a glass, in particular a glass comprising amorphous silica.

### DESCRIPTION OF THE FIGURES

FIG. 1: general view of a system for deposition by atmospheric plasma.

FIG. 2: sectional view of a cylindrical deposition system.

FIG. 3: XPS (X-ray Photoelectron Spectroscopy) spectra of the sample treated in Example 2.

FIG. 4: detail of the XPS spectrum of the sample treated in Example 2, carbon peak.

FIG. 5: illustrates the XPS spectrum of the non-treated PVC.

FIG. 6: illustrates the XPS spectrum of the non-treated polyethylene.

FIG. 7: illustrates the XPS spectrum of the sample treated in Example 4.

FIG. 8: illustrates the XPS spectrum of steel after cleaning, and before deposition.

FIG. 9: illustrates the XPS spectrum of the sample treated in Example 6.

FIG. 10: illustrates the XPS spectrum of the sample treated in Example 8.

FIG. 11: illustrates the XPS spectrum of polytetrafluoroethylene (PTFE).

### DETAILED DESCRIPTION OF EMBODIMENTS OF THE INVENTION

The present invention discloses a method for depositing a fluorinated polymeric layer via a plasma technology operating at atmospheric pressure. It allows deposition of a fluorinated polymer layer via a fluorinated compound which is injected into the plasma, or into the post-discharge area of the latter. In the selected example, the monomer is a liquid at room temperature (25° C.), perfluorohexane, and is carried away into the plasma via a carrier gas, argon. In the present case, the plasma is generated in a discharge with a dielectric barrier, the sample to be treated being placed inside the discharge, or at the immediate exit of the latter (post-discharge).

In order to improve control of the deposition thickness and reduce emission of fluorinated pollutant vapors, the partial pressure of fluorinated compound in the plasma is maintained at low values, preferably less than 10 mbars. This low pressure is obtained either by maintaining the fluorinated liquid at a low temperature, or by selecting a fluorinated liquid having a vapor pressure of less than 10 mbars at room temperature.

The use of these low concentrations of fluorinated compounds within the plasma in particular allows deposition of ultra-thin layers, with which transparent layers may be obtained. Moreover, as the adhesive and wettability properties are essentially related to interactions over very short distances, the thinness of the deposition does not degrade these properties.

The present invention further has the advantage of allowing any surface to be treated insofar that the geometry of the discharge is adapted and has the advantage of proceeding in a single, simple and rapid step.

In a particular embodiment of the invention, the fluorinated compound is of the type:

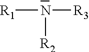

wherein R₁, R₂ and R₃ are groups of the perfluoroalkane type, of formula CₙF₂ₙ₊₁. The advantage of such a type of molecule lies in the weakness of C—N bond (2.8 eV of binding energy) relatively to the C—C bond (4.9 eV of binding energy) promoting a fragmentation scheme of the precursor in the plasma producing radicals .R₁, .R₂ and .R₂, and, therefore, allowing better control of the nature of the reactive species within the plasma discharge and in the post-discharge area of the latter. Surprisingly, the use of this type of molecule induces the incorporation of a small amount of nitrogen into the deposited film.

More particularly, long fragments improve the properties of the deposited layers. Perfluorotributylamine ((C₄F₉)₃N) in particular has exhibited excellent properties.

In the examples hereafter, the substrate consists of a film of PVC (polyvinyl chloride), PE (polyethylene), steel or glass, without this being limiting, it being understood that for one skilled in the art this technology is immediately transposable to any type of substrate.

### EXEMPLARY EMBODIMENTS

### Example 1

Example 1 shows a deposit of perfluorohexane on PVC, achieved in post-discharge under the following conditions:

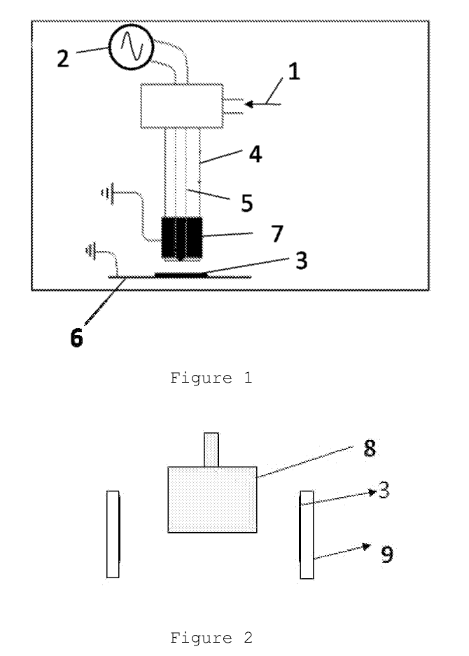

A sample 3, as a PVC film of 4 cm×4 cm of the Solvay brand is cut out, cleaned with methanol and isooctane and placed at the outlet (at 0.05 cm) of a cold plasma torch (FIG. 1) (discharge with a dielectric barrier) operating at atmospheric pressure. The fluorinated monomer (perfluorohexane) is placed in a glass (Pyrex) bubbler immersed in a Dewar vessel containing a mixture of acetone and dry ice. The temperature of the mixture, and therefore of the monomer, is about −80° C. The vapor pressure of perfluorohexane at this temperature is about 1.2 mbars. An argon flow is then sent into the bubbler, with an initial overpressure of 1.375 bars. The argon/perfluorohexane gas mixture 1 is carried away into the inside of the torch. A plasma is initiated with a voltage of 3,200 Volts and a frequency of 16 kHz for 1 minute.

### Example 2

Example 2 shows a deposit of perfluorohexane on PVC produced in a discharge with a dielectric barrier under the following conditions.

The sample is attached onto the inside of the external electrode 9 of a discharge with a cylindrical dielectric barrier. The <<hot>> electrode 8, the one to which the voltage is applied, is the internal electrode covered with an alumina cup. Alumina cement provides the seal (FIG. 2).

The fluorinated monomer is brought into the discharge as in Example 1. A treatment of 1 minute at a voltage of 3,000 V and a frequency of 20 kHz is applied subsequently (treatment in the discharge area).

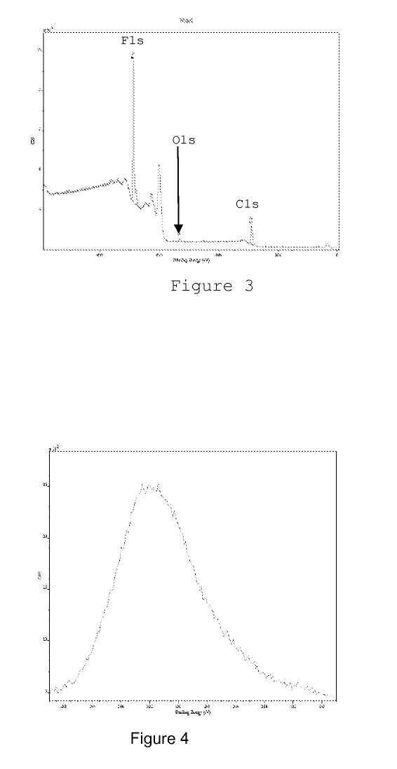

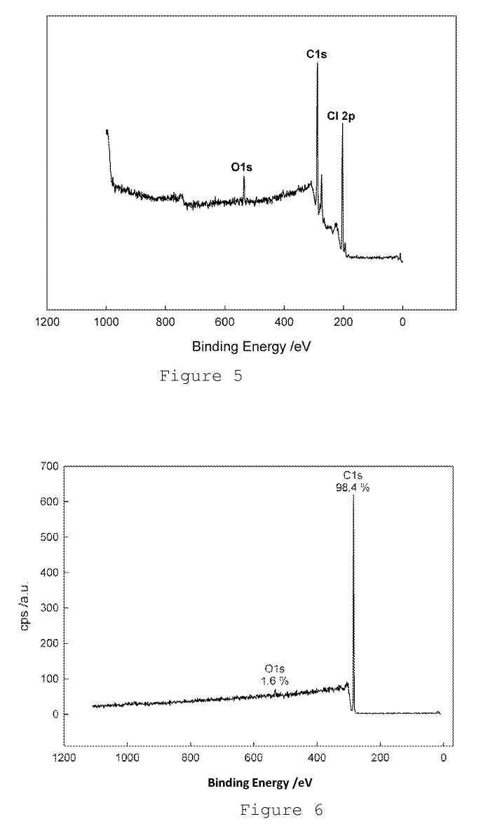

The unambiguous presence of a fluorinated layer at the surface of the PVC film is proved by X photoelectron spectroscopy. The spectra of FIGS. 3 and 4 illustrate full survey and magnification of the carbon area. The presence of fluorine of CF₂ groups is clearly identified via the fluorine peak located at 689 eV and the position of the carbon peak, 291.5 eV actually corresponds to the carbon —CF₂—.

The stability of the deposited layer is attested by the preservation of the value of the contact angle after aging (in air) for one week.

### Example 3

Example 3 is identical with Example 1, except for the substrate, which in this example is polyethylene.

### Example 4

Example 4 is identical with Example 3, except for the substrate, which in this example is polyethylene. The spectrum of a PE sample (FIG. 6) contains a main peak around 285 eV. It corresponds to the carbon (C1s). The presence of a peak of low intensity is also noted around 530 eV, the latter corresponds to contaminating oxygen.

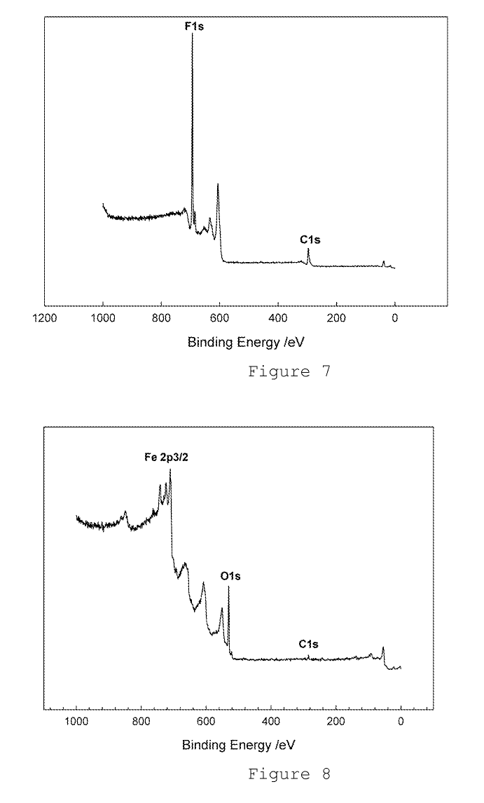

After exposure to the plasma, the spectrum includes two components (FIG. 7), one at 689.7 eV, F1s and the other one at 292.1 eV, C1s, of the CF₂ type. The calculated composition is 61.2% of fluorine, 38.8% of carbon.

### Example 5

In Example 5, a deposit of a fluorinated layer on a steel substrate was made according to the same deposition procedure as for Examples 1 and 3, except that the monomer this time was perfluorotributylamine, the temperature of which was maintained at 25° C. The vapor pressure of perfluorotributylamine at 25° C. is 1.75 mbars.

### Example 6

In Example 6, a deposit of a fluorinated layer on a steel substrate was made according to the same deposition procedure as for Examples 2 and 4, except that the monomer this time was perfluortributylamine, the temperature of which was maintained at 25° C. The vapor pressure of perfluorotributylamine at 25° C. is 1.75 mbars, which allows it to be used at room temperature.

After conventional cleaning, the steel surface is still contaminated by oxygen and carbon. By slightly ion-spraying the sample, it is possible to partly remove this contamination (FIG. 8: XPS before treatment).

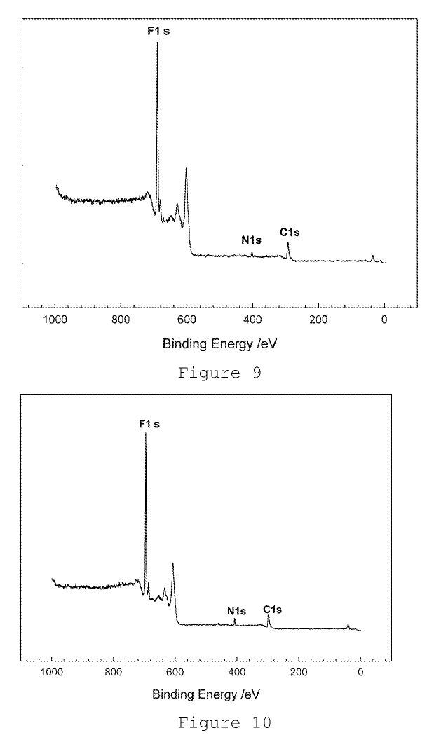

After exposure to the plasma, the XPS spectrum includes 2 main components, the occurrence of a new component of low intensity (FIG. 9) is also noted. The main components are located at 689.7 eV (F1s) and 292.1 eV (C1s), of the CF₂ type. The new component is located around 400 eV, it corresponds to nitrogen (N1s). The calculated composition is 62.2% of fluorine, 33.3% of carbon and 4.5% of nitrogen. The component due to nitrogen is only present when the monomer containing nitrogen (C₁₂F₂₇N) is used.

### Example 7

In Example 7, a deposit of a fluorinated layer on a glass substrate was made according to the same deposition procedure as for Example 5.

### Example 8

In Example 8, a deposit of a fluorinated layer on a glass substrate was made according to the same deposition procedure as for Example 6.

As earlier, after exposure to the plasma, the spectrum includes two main components, the occurrence of a new component of low intensity (FIG. 10) is also noted. The main components are located at 689.7 eV (F1s) and 292.1 eV (C1s), of the CF₂ type. The new component is located around 400 eV, it corresponds to nitrogen (N1s). The calculated composition is 63.0% of fluorine, 32.8% of carbon and 4.2% of nitrogen.

### Example 9

A sample prepared according to Example 2, was subject to aging for one week in the atmosphere, at room temperature.

### Example 10 (Comparative)

A PVC sample was exposed to an atmospheric plasma of argon, in the post-discharge area, according to the same experimental scheme as in Example 1, in the absence of the fluorinated monomer.

### Example 11 (Comparative)

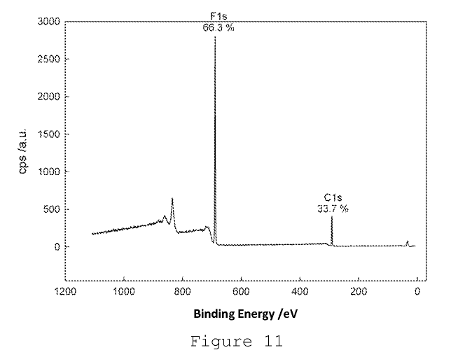

A PVC sample was exposed to an atmospheric plasma of argon, in the discharge area, according to the same experimental scheme as in Example 2, in the absence of fluorinated monomer. In Examples 1-9, the energy of the peaks as well as the composition of the surface obtained after treatment are very close to the values obtained for a PTFE sample. Indeed, the PTFE spectra (FIG. 11) shown in the literature also include 2 peaks, one at 689.7 eV corresponding to fluorine and the other one at 292.5 eV corresponding to carbon (C1s). The composition of the surface is 66.6% of fluorine and 33.4% of carbon.

Table 1 shows the contact angles of water on the surfaces of the different examples and on the surfaces of non-treated substrates.

TABLE 1

| | Contact angle of the water on the surface |
|---|---|
| PVC | 81° |
| Example 1 | 111° |
| Example 2 | 111° |
| PE | 79° |
| Example 3 | 111° |
| Example 4 | 111° |
| Steel | 78° |
| Example 5 | 111° |
| Example 6 | 111° |
| Glass | 35° |
| Example 7 | 112° |
| Example 8 | 112° |
| Example 9 | 112 |
| Example 10 | 40° |
| Example 11 | 22° |
| PTFE | 105° |

In all these examples, the deposited polymer layers are perfectly transparent and invisible to the naked eye.

The method may be applied to all cold atmospheric plasmas, regardless of the energy injection method (not only DBD, but RF, microwaves, . . . ).

The method may be applied to all surfaces which have to be covered with a fluorinated layer: glass, steel, polymer, ceramic, paint, metal, metal oxide, mixed, gel.

A hydrophobic layer may be deposited only if the initial monomer does not contain any oxygen or hydrogen. Indeed, the presence in the plasma discharge, or in the post-discharge area of oxygenated radicals directly induces the incorporation of hydrophilic oxygenated functions into the deposited layer on the one hand, the presence of hydrogenated radicals generally induces their recombination with residual oxygen or humidity, giving rise to the occurrence of OH. radicals, which are very hydrophilic, on the other hand.

### CAPTIONS OF THE REFERENCES IN THE FIGURES

1 Fluorinated compound/argon mixture flow
2 Generator
3 Sample
4 Alumina or metal electrode
5 Electrode covered with alumina
6 Copper support (grounded)
7 Copper electrode (grounded)
8 Internal mobile <<hot>> electrode
9 External metal electrode

1-15. (canceled)

16. A method for depositing a fluorinated layer on a substrate, comprising the injection of a gas mixture including a fluorinated compound and a carrier gas in a discharge or post-discharge area of an atmospheric plasma at a pressure comprised between 0.8 and 1.2 bars, wherein said fluorinated compound has a boiling temperature at a pressure of 1 bar above 25° C. and in that the fluorinated compound is of the type: 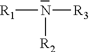
wherein R₁, R₂ and R₃ are groups of the perfluoroalkane type, of formula CₙF₂ₙ₊₁.

17. The method according to claim 1 comprising the steps of:
bringing the carrier gas into contact with the liquid fluorinated compound;
saturating said carrier gas with vapor of said fluorinated compound to form a gas mixture;
bringing said gas mixture into the discharge area of an atmospheric plasma;
placing a substrate in the discharge or post-discharge area of said atmospheric plasma;
wherein said fluorinated compound comprises an oxygen and hydrogen free compound.

18. The method according to claim 16 wherein said method is free of any plasma-free post-treatment.

19. The method according to claim 16, wherein said fluorinated compound comprises perfluorotributylamine ((C₄F₉)₃N).

20. The method according to claim 16, wherein the vapor pressure of said fluorinated compound at room temperature is comprised between 1 mbar and 1 bar.

21. The method according to claim 20, wherein the vapor pressure of said fluorinated compound at room temperature is comprised between 0.5 mbars and 10 mbars.

22. The method according to claim 16, wherein the partial pressure of said fluorinated compound in said carrier gas is regulated by controlling the temperature of a bath of said fluorinated compound into which the carried gas is injected before injection into the plasma.

23. The method according to claim 22, wherein the temperature of the bath is maintained at a temperature at which the vapor pressure of said compound is less than 10 mbars.

24. The method according to claim 16, wherein said atmospheric plasma is produced by a device of the dielectric barrier type.

25. The method according to claim 16, wherein said atmospheric plasma is produced by a device of the type using microwaves.

26. The method according to claim 16, wherein the substrate comprises a deposition surface comprising a polymer.

27. The method according to claim 26, wherein the substrate comprises a deposition surface comprising polyvinyl chloride or polyethylene.

28. The method according to claim 16, wherein the substrate comprises a deposition surface comprising a metal or a metal alloy.

29. The method according to claim 28, wherein the substrate comprises a deposition surface comprising steel.

30. The method according to claim 1, wherein the substrate comprises a deposition surface comprising glass.
